(19) United States
(12) Patent Application Publication
(10) Pub. No.: US 2010/0269753 A1
(43) Pub. Date: Oct. 28, 2010

(54) METHOD AND APPARATUS FOR TREATING A GAS STREAM

(76) Inventors: Andrew James Seeley, Bristol (GB); Raul Antonio Abreu Abreu, West Sussex (GB)

Correspondence Address: Edwards Vacuum, Inc., 2041 MISSION COLLEGE BOULEVARD, SUITE 260, SANTA CLARA, CA, 95054, US

(21) Appl. No.: 12/301,789

(22) PCT Filed: May 21, 2007
(86) PCT No.: PCT/GB2007/050277

§ 371 Date: Jul. 13, 2010

(30) Foreign Application Priority Data
Jun. 28, 2006 (GB) 0612814.4

(51) Int. Cl. C23C 16/00; B01D 53/32; C25B 9/00

(52) U.S. Cl. 118/723 R; 204/157.15; 204/242; 204/277

(57) ABSTRACT

Apparatus is described for treating a gas stream. The apparatus comprises a gas passage (72) for receiving the gas stream, a plurality of hollow cathodes (94) located about the gas passage (72), means for supplying to the hollow cathodes (94) a gaseous source of reactive species for reacting with a component of the gas stream, means for applying a potential to the hollow cathodes (94) to form the reactive species from said source, and a reaction chamber (110) for receiving the gas stream and the reactive species.

The present invention relates to a method of, and apparatus for, treating a gas stream. The invention may be used in the treatment of a gas stream exhausted from a process chamber to which gas is supplied by a pulsed gas delivery system, or in the treatment of a gas stream exhausted from any other process chamber.

Pulsed gas delivery systems are commonly used in the formation of multi-layer thin films on a batch of substrates located in a process chamber. One such technique for forming thin films on substrates is atomic layer deposition (ALD), in which gaseous reactants, or “precursors”, are sequentially delivered to a process chamber to form very thin layers, usually on an atomic-layer scale, of materials on the substrates.

By way of example, a high dielectric constant capacitor may be formed on a silicon wafer using an ALD technique. Dielectric layers that may be deposited using an ALD technique may include hafnium oxide (HfO₂), aluminium oxide (Al₂O₃), titanium dioxide (TiO₂), zirconium oxide (ZrO₂) or any mixture thereof. Precursors for the formation of such dielectric thin films have the general formula AlR₃, where R is an organic radical, M(NR₂)₄, where M is one of Ti, Zr and Hf, and M(NR′R)₄, where R and R′ are different organic radicals.

In overview, the first precursor delivered to the process chamber is adsorbed on to the surfaces of the substrates within the process chamber. The non-adsorbed first precursor is drawn from the process chamber by a vacuum pumping system, and the second precursor is then delivered to the process chamber for reaction with the first precursor to form a layer of deposited material. In the deposition chamber, the conditions immediate to the substrates are optimised to minimise gas-phase reactions and maximise surface reactions for the formation of a continuous film on each substrate. Any non-reacted second precursor and any by-products from the reaction between the precursors is then removed from the process chamber by the pumping system. Depending on the structure being formed within the process chamber, the first precursor, or a third precursor, is then delivered to the process chamber.

A purge step is typically carried out between the delivery of each precursor, for example by delivering a purge gas, such as N₂ or Ar, to the chamber between the delivery of each precursor. The purpose of the purge gas delivery is to remove any residual precursor from the process chamber so as to prevent unwanted reaction with the next precursor supplied to the chamber.

In practice, only around 5% or less of the precursors supplied to the process chamber are consumed during the deposition process, and so the gas drawn from the chamber during the process chamber will, between supplies of purge gas to the chamber, alternately be rich in the first precursor, and then rich in the second precursor.

In convention vacuum pumping systems, the gases drawn from the process chamber enter a common foreline leading to a vacuum pump. In the event that the non-reacted precursors meet within the vacuum pumping system, cross-reaction of the precursors can occur, and this can result in both the deposition of solid material and the accumulation of powders within the foreline and the vacuum pump. Particulates and powders that have accumulated within the pump can effectively fill the vacant running clearance between the rotor and stator elements of the pump, leading to a loss of pumping performance and ultimately pump failure. Periodic pump cleaning or replacement is then required to maintain pumping performance, resulting in costly process downtime and increasing manufacturing costs.

It is an aim of at least the preferred embodiment of the present invention to seek to solve this problem.

In a first aspect, the present invention provides a method of treating a gas stream exhausted from a process chamber to which a first gaseous precursor and a second gaseous precursor are alternately supplied, the method comprising the steps, upstream from a vacuum pump used to draw the gas stream from the chamber, of conveying the gas stream through a gas passage surrounded by a plurality of hollow cathodes, conveying through the hollow cathodes a source of reactive species for reacting with one of the first and second gaseous precursors, applying a potential to the hollow cathodes to form the reactive species from said source, and, downstream from the gas passage, mixing the reactive species with the gas stream.

Through the application of a (negative) potential to the hollow cathodes, the source of reactive species can be dissociated into reactive species, such ions, radicals and electrons, in a plasma. By deliberately reacting, say, unconsumed first gaseous precursor with the reactive species emitted from the hollow cathodes before it reaches the pump, reaction within the pump of the unconsumed first gaseous precursor with unconsumed second gaseous precursor subsequently drawn from the chamber by the pump can be inhibited. Conveying the source of reactive species through the hollow cathodes in isolation from the gas to be treated can inhibit the deposition of by-products from the reaction between the reactive species and the gas to be treated within the hollow cathodes.

The source of the reactive species is preferably a gas that is relatively cheap, safe and readily available. In order to minimise the number of gas supplies the source of reactive species may be the second gaseous precursor, which is supplied from a second precursor supply both to the process chamber and to the hollow cathodes to form reactive species for reaction with the first gaseous precursor. In this case, the source of reactive species may be either an oxidising agent or a reducing agent used in the process conducted within the process chamber. In the preferred embodiments, the source of reactive species is an oxidising agent, and so the second gaseous species may be ozone, and the first gaseous precursor may be an organometallic precursor, which may comprise one of hafnium and aluminium. Examples include tetrakis(ethylmethylamino)hafnium (TEMAH) and trimethyl aluminium (TMA).

As an alternative to using the second gaseous precursor as the oxidant, an oxidant such as O₂ may be supplied to the hollow cathodes from a separate source to form oxygen radicals and ions for reaction with the first gaseous precursor.

As this method is suitable for use in treating a gas stream other than that exhausted from a process chamber to which a first gaseous precursor and a second gaseous precursor are alternately supplied, in a second aspect the present invention provides a method of treating a gas stream, the method comprising the steps of conveying the gas stream through a gas passage surrounded by a plurality of hollow cathodes, conveying through the hollow cathodes a gaseous source of reactive species for reacting with a component of the gas stream, applying a potential to the hollow cathodes to form the reactive species from said source, and, downstream from the gas passage, mixing the reactive species with the gas stream.

In either of the above aspects, each hollow cathode preferably comprises a hollow cylindrical tube. The cylindrical tubes are preferably substantially parallel to the gas passage. The cylindrical tubes preferably comprise a plurality of bores formed in an electrically conductive body at least partially housing the gas passage. The outlets from the hollow cathodes are preferably substantially co-planar with the outlet from the gas passage. A plurality of the gas passages may be provided, and arranged such that the gas stream passes through the gas passages in parallel, each gas passage being surrounded by a plurality of hollow cathodes.

The gas passage preferably passes through a plenum chamber having an inlet for receiving the source of reactive species, and a plurality of outlets from which the source of reactive species is supplied to the hollow cathodes. The plenum chamber is preferably formed from electrically insulating material. An anode is preferably located downstream from the gas passage and the hollow cathodes, the anode having apertures aligned with the gas passage and the hollow cathodes to permit the gas stream and the reactive species to pass through the anode. The reactive species may subsequently mix with the gas stream within a reactor chamber located downstream from the gas passage. The reactor chamber may be either heated or thermally insulated to promote reaction between the reactive species and the component of the gas stream.

In the event that the reaction results in the formation of solid material, a separator may be provided between the gas passage and the vacuum pump for separating from the gas stream solid material, such as dust and/or particulates, produced from the reaction. The separator may be provided by any trap device for removing solid material from a gas stream. One example is a dead-leg type of trap device. In the preferred embodiment, the separator is provided by a cyclone separator. An advantage associated with the use of a cyclone separator to separate the solid material from the gas stream is that the solid material will settle out in the bottom of the cyclone separator without increasing the impedance of the separator to the flow of the gas stream. Two or more cyclone separators may be provided in parallel to increase gas conductance.

In a third aspect the present invention provides apparatus for treating a gas stream, the apparatus comprising a gas passage for receiving the gas stream, a plurality of hollow cathodes located about the gas passage, means for supplying to the hollow cathodes a gaseous source of reactive species for reacting with a component of the gas stream, means for applying a potential to the hollow cathodes to form the reactive species from said source, and a reaction chamber for receiving the gas stream and the reactive species.

In a fourth aspect the present invention provides apparatus for treating a gas stream exhausted from a process chamber to which a first gaseous precursor and a second gaseous precursor are alternately supplied, the apparatus comprising a gas passage for receiving the gas stream, a plurality of hollow cathodes located about the gas passage, means for supplying to the hollow cathodes a gaseous source of reactive species for reacting with one of the first and second gaseous precursors, means for applying a potential to the hollow cathodes to form the reactive species from said source, and a reaction chamber for receiving the gas stream and the reactive species.

In a fifth aspect the present invention provides an atomic layer deposition apparatus comprising a process chamber, a first gaseous precursor supply for supplying a first gaseous precursor to the chamber, a second gaseous precursor supply for supplying a second gaseous precursor to the chamber, a vacuum pump for drawing a gas stream from the process chamber, and, between the process chamber and the vacuum pump, a plurality of gas passages for receiving the gas stream from the process chamber, and a plurality of hollow cathodes located about the gas passages for receiving second gaseous precursor from the second precursor gas supply, the apparatus comprising means for applying a potential to the hollow cathodes to form from the second gaseous precursor reactive species for reacting with first gaseous precursor within the gas stream to form solid material, a reaction chamber for receiving the gas stream and the reactive species, and a separator for receiving a gas stream exhausted from the reaction chamber and separating solid material from that gas stream.

Features described above in relation to method aspects of the invention are equally applicable to apparatus aspects, and vice versa.

Preferred features of the present invention will now be described, by way of example only, with reference to the accompanying drawings, in which:

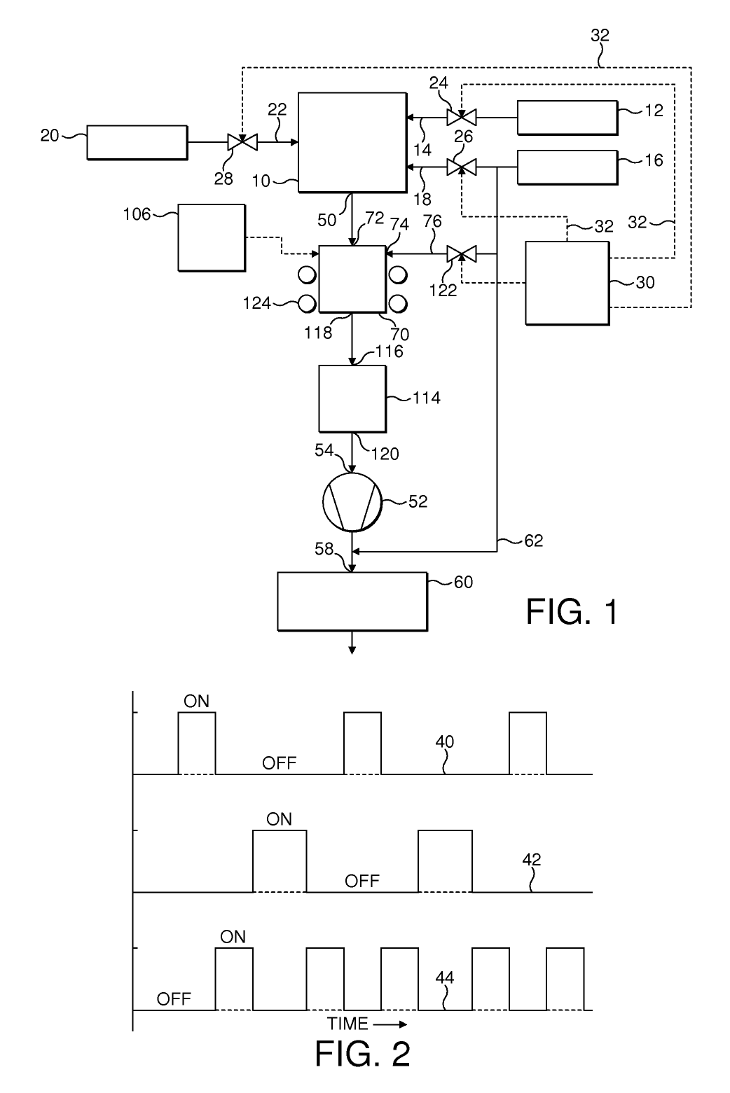

FIG. 1 illustrates schematically an atomic layer deposition apparatus including apparatus for treating the gas stream exhaust from the process chamber;

FIG. 2 illustrates the sequence of supply of gases to the process chamber of the apparatus of FIG. 1;

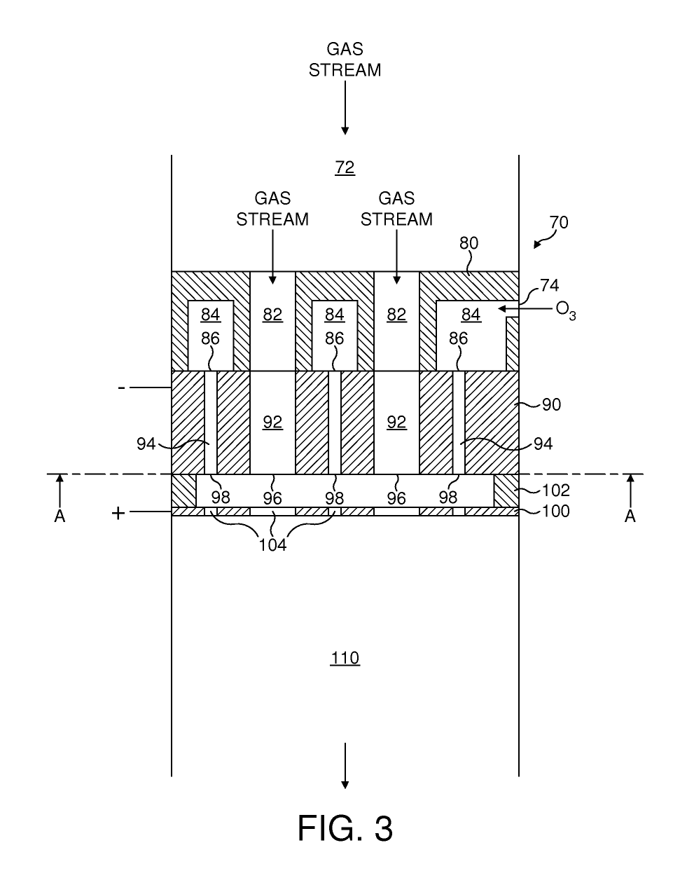

FIG. 3 illustrates in more detail the apparatus for treating the gas stream;

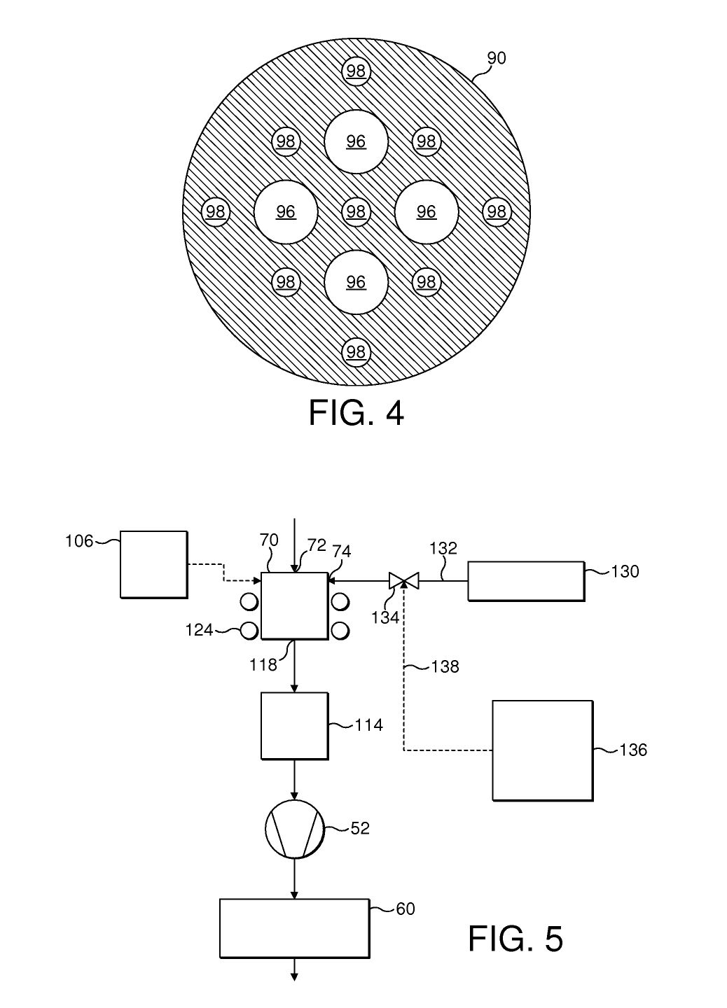

FIG. 4 is a cross-sectional view of the apparatus of FIG. 3; and

FIG. 5 illustrates apparatus for treating a gas stream separate from any process apparatus.

With reference first to FIG. 1, an atomic layer deposition (ALD) apparatus comprises a process chamber 10 for receiving a batch of substrates to be processed simultaneously within the process chamber 10. The process chamber 10 receives separately and alternately two or more different gaseous reactants or precursors for use in forming layers of material on the exposed surfaces of the substrates. In the example illustrated in FIG. 1, a first precursor supply 12 is connected to the process chamber 10 by a first precursor supply line 14 for supplying a first precursor to the process chamber 10, and a second precursor supply 16 is connected to the process chamber 10 by a second precursor supply line 18 for supplying a second precursor to the process chamber 10. A purge gas supply 20 is also connected to the process chamber 10 by a purge gas supply line 22 for supplying a purge gas such as nitrogen or argon to the process chamber 10 between the supply of the precursors to the process chamber 10.

The supply of the precursors and the purge gas to the process chamber 10 is controlled by the opening and closing of gas supply valves 24, 26, 28 located in the supply lines 14, 18, 22 respectively. The operation of the gas supply valves is controlled by a supply valve controller 30 which issues control signals 32 to the gas supply valves to open and close the valves according to a predetermined gas delivery sequence. A typical gas delivery sequence involving two gaseous precursors and a purge gas is illustrated in FIG. 2. The first trace 40 represents the stepped delivery sequence for the first gaseous precursor, and the second trace 42 represents the stepped delivery sequence for the second gaseous precursor. As described above, the first and second precursors are alternately supplied to the chamber to form layers of solid material on the batches of substrates located within the process chamber 10. The duration of each pulsed delivery of precursor to the process chamber 10 is defined for the particular process to be performed within the process chamber 10; in this example, the duration of each pulsed delivery of the second precursor to the process chamber 10 is longer than that for the first precursor. The third trace 44 represents the stepped delivery sequence for the purge gas that is introduced into the process chamber 10 between the delivery of first and second gaseous precursors to flush the process chamber 10 before introducing the next gaseous precursor.

Returning to FIG. 1, a vacuum pumping system is connected to the outlet 50 of the process chamber 10 for drawing a gas stream from the process chamber 10. The pumping system comprises a vacuum pump 52 for receiving the gas stream through an inlet 54 thereof and exhausting the gas stream at an elevated pressure through an exhaust 56 thereof. The gas stream exhausted from the vacuum pump 52 is conveyed to an inlet 58 of an abatement device 60, for example a thermal processing unit or a wet scrubber, for removing one or more species from the gas stream before it is exhausted to the atmosphere.

In one example, the first gaseous precursor is an organometallic precursor containing one of hafnium and aluminium, such as tetrakis(ethylmethylamino) hafnium (TEMAH) or trimethyl aluminium (TMA), and the second gaseous precursor is an oxidant, such as ozone. The second precursor supply 16 may therefore be provided by an ozone generator. Currently available ozone generators can be difficult to start and stop in synchronisation with the pulsed delivery sequence of ozone to the process chamber 10. In view of this, the ozone generator 16 may be continuously generating ozone during the ALD process, and when ozone is not being delivered to the process chamber 10 the ozone may be diverted along ozone supply line 62 to a location downstream from the vacuum pump 52, for example to the inlet of a backing pump (not illustrated) provided between the vacuum pump 52 and the abatement device 60, or directly to a second inlet of the abatement device 60, where the ozone may assist in the abatement of the gas stream exhausted from the vacuum pump 52.

In view of the alternating supply of first and second gaseous precursors to the process chamber 10, the gas stream drawn from the process chamber 10 will alternate between a first precursor-rich gas stream, comprising unconsumed first precursor and by-products from the reaction between the precursors, and a second precursor-rich gas stream, comprising unconsumed second precursor and the by-products, with a purge gas-rich gas stream being drawn from the process chamber 10 between these precursor-rich gases. Each of the precursor-rich gas streams is also likely to contain traces of purge gas and other contaminants.

In order to inhibit mixing of the unconsumed precursors within the vacuum pump 52, which could lead to undesirable reaction between the precursors and the formation of dust and/or powders within the vacuum pump, apparatus 70 is provided between the outlet 50 of the process chamber 10 and the inlet 54 of the vacuum pump 52 to treat the gas stream exhausted from the process chamber 10 so as to reduce the amount of one of the first and second precursors that enters the vacuum pump 52. In the example illustrated in FIG. 1, the amount of the first precursor entering the vacuum pump 52 is reduced.

The apparatus 70 for treating the gas stream exhausted from the process chamber 10 has a first inlet 72 for receiving the gas stream exhausted from the process chamber 10, and a second inlet 74 for receiving a source of reactive species for reacting with the chosen precursor to be at least partially removed from the gas stream. In the illustrated example, a supply for supplying the source of reactive species to the apparatus 70 is conveniently provided by the ozone generator 16. A reactant supply line 76 is connected between the ozone supply line 62 and the second inlet 74 of the gas mixing chamber 70 to supply ozone to the apparatus 70.

Part of the apparatus 70 is illustrated in more detail in FIG. 3. The apparatus 70 comprises an electrically insulating body 80 having a plurality of parallel, cylindrical bores 82 extending therethrough for receiving the gas stream from the first inlet 72. The body 80 also defines a plenum chamber 84 located about the bores 82, and which receives the source of reactive species from the second inlet 74. The plenum chamber 84 has a plurality of cylindrical outlets 86 surrounding the bores 82 through which the source of reactive species is exhausted from the plenum chamber 84.

The apparatus 70 also comprises a cathode 90 located downstream from the electrically insulating body 80. The cathode 90 is provided by an electrically conducting body having a first set of parallel, cylindrical bores 92 extending therethrough for receiving the gas stream from the channels 82. The bores 92 in the cathode 90 have substantially the same diameter as the bores 82 in the body 80. The bores 82 of the body 80 and the bores 92 of the cathode 90 together define gas passages arranged such that the gas stream passes through the gas passages in parallel.

The cathode 90 also has a second set of bores 94 extending therethrough for receiving the gas stream from the outlets 86 of the body 80. The diameter of the bores 94 is smaller than the diameter of the bores 92. The bores 94 are axially aligned with the outlets 86 from the plenum chamber 84, and are arranged substantially parallel to the bores 92. The outlets 96 from the bores 92 are substantially co-planar with the outlets 98 from the bores 94. With reference to FIG. 4, each of the bores 92 is surrounded by a plurality of the smaller bores 94, in this example by four bores but the bores 92 may be surrounded by any number of the smaller bores 94.

The apparatus further comprises an anode 100 spaced from the cathode by an electrical insulator 102. The anode 100 has a plurality of apertures 104 which are aligned with the outlets 96, 98 of the bores 92, 94 of the cathode 90. A power source 106 is provided to charge the cathode 90 to a cathode (negative) potential and the anode 100 to an anode (positive) potential.

The application of the negative potential to the cathode 90 causes the bores 94 to act as hollow cathodes, which results in the dissociation of the source of reactive species, in this example ozone, into reactive species, in this example electrons, oxygen ions and oxygen radicals, in a plasma. The reactive species and the gas stream pass through the apertures 104 in the anode 100 and enter a reaction chamber 110 within which the reactive species react with unconsumed first gaseous precursor in the gas stream.

The source of reactive species is preferably chosen so that the reaction that takes place within the reaction chamber 110 replicates the reaction that would occur between unconsumed first and second gaseous precursors within the vacuum pump 52. Therefore, a product from the reaction between the reactive species and the first gaseous precursor is the solid material, such as a dust and/or powder, that would otherwise be formed in the vacuum pump 52 through the reaction between the unconsumed precursors. Consequently, the a separator 114 may be provided for removing this solid material from the gas stream exhausted from the reaction chamber 110 before it enters the vacuum pump 52. With reference to FIG. 1, the separator 114 has an inlet 116 connected to an outlet 118 of the apparatus 70. The separator 114 is preferably a cyclone separator, which receives the solid material-laden gas stream from the apparatus 70, and, in a manner known in the art, separates the solid material from the gas stream, retaining the solid material therewithin and exhausting the gas stream from an outlet 120 thereof to the inlet 54 of the vacuum pump 52.

The supply of the source of reactive species to the apparatus 70 is controlled by the opening and closing of reactant supply valve 122 located in the reactant supply line 76. The operation of the reactant supply valve 122 is controlled by the supply valve controller 30, which issues control signals 32 to the reactant supply valve 76 to open and close in synchronisation with the delivery of the first gaseous precursor to the process chamber 10, so that the source of reactive species is supplied to the apparatus 70 with a stepped delivery sequence that is similar to that for the first gaseous precursor. The amount of source of reactive species periodically delivered to the apparatus 70 is preferably at least sufficient to react with the amount of the first gaseous precursor that is supplied to the process chamber 10.

In order to increase the reaction rate between the reactive species and the first gaseous precursor within the reaction chamber 110, a heater 124 may optionally extend about the reaction chamber 110 for heating the reaction chamber 110. Alternatively, the reaction chamber 110 may be thermally insulated.

In the example illustrated in FIG. 1, the apparatus 70 is separate from the separator 114. However, the apparatus 70 may be mounted on, or integral with, the separator 114. Two or more separators 114 may be provided in parallel to enable one separator to be serviced while the other is operational.

The apparatus 70 has been described above as part of an ALD apparatus 10. However, the apparatus 70 may be used to treat gas streams other than those exhausted from an ALD process chamber. For example, the apparatus 70 may be used to treat gases exhausted from a CVD or other deposition chamber, or any other gas stream containing a component, for example NH₃, which may be detrimental to the vacuum pump 52. FIG. 5 illustrates an example in which the apparatus is used to treat any gas stream. In view of the absence of the source of the second precursor gas for supplying the source of reactive species to the second inlet 74 of the apparatus 70, a separate source 130 of reactive species, in this example an oxidant such as oxygen, is connected to the second inlet 74 by a reactant supply line 132. The supply of oxygen to the apparatus 70 is controlled by opening and closing valve 134. As illustrated in FIG. 5, a controller 136 may be provided by issuing signals 138 to the valve 134 to control the supply of oxygen to the apparatus 70. Depending on the nature of the reaction between the reactive species and the component of the gas stream, a separator 114 may again be provided downstream from, or integral with, the apparatus 70. This separator 114 may be provided by a cyclone trap for removing particulates from the gas stream, a cold trap for removing condensable species from the gas stream, or a hot trap.

1. A method of treating a gas stream, the method comprising the steps of:
conveying the gas stream through a gas passage surrounded by a plurality of hollow cathodes;
conveying through the plurality of hollow cathodes a gaseous source of reactive species for reacting with a component of the gas stream exhausted from the gas passage;
applying a potential to the hollow cathodes to form the reactive species from said source; and
mixing the reactive species with the gas stream downstream from the gas passage.

2. The method according to claim 1 wherein each hollow cathode comprises a hollow cylindrical tube.

3. The method according to claim 2 wherein the cylindrical tubes are substantially parallel to the gas passage.

4. The method according to claim 2 wherein the cylindrical tubes comprise a plurality of bores formed in an electrically conductive body at least partially housing the gas passage.

5. The method according to claim 1 comprising the step of positioning an anode downstream from the gas passage and the hollow cathode, the anode having apertures aligned with the gas passage and the hollow cathodes.

6. The method according to claim 1 wherein the outlets from the hollow cathodes are substantially co-planar with the outlet from the gas passage.

7. The method according to claim 1 comprising the step of arranging a plurality of said gas passages such that the gas stream passes through the gas passages in parallel, each gas passage being surrounded by a plurality of hollow cathodes.

8. The method according to claim 1 comprising the step of mixing the reactive species with the gas stream within a reactor chamber located downstream from the gas passage.

9. The method according to claim 8 comprising the step of heating the reactor chamber to promote reaction between the reactive species and the component of the gas stream.

10. The method according to claim 8 comprising the step of thermally insulating the reactor chamber to promote reaction between the reactive species and the component of the gas stream.

11. The method according to claim 1 comprising the step of conveying the gas stream to a separator to separate solid material from the gas stream.

12. The method according to claim 11 wherein the separator is a cyclone separator.

13. The method according to claim 1 wherein the source of the reactive species is an oxidant.

14. The method according to claim 13 wherein the source of the reactive species is oxygen or ozone.

15. A method according to claim 1 wherein said component of the gas stream is one of a first gaseous precursor and a second gaseous precursor alternately supplied to the process chamber

16. A method of treating a gas stream exhausted from a process chamber to which a first gaseous precursor and a second gaseous precursor are alternately supplied, the method comprising the steps of:
upstream from a vacuum pump used to draw the gas stream from the chamber, conveying the gas stream through a gas passage surrounded by a plurality of hollow cathodes;
conveying through the hollow cathodes a source of reactive species for reacting with one of the first and second gaseous precursors;
applying a potential to the hollow cathodes to form the reactive species from said source; and
downstream from the gas passage, mixing the reactive species with the gas stream.

17. The method according to claim 15 wherein said one of the first and second gaseous precursors is the first gaseous precursor, and the source of reactive species is the second gaseous precursor.

18. The method according to claim 17 wherein said one of the first and second gaseous precursors is an organometallic precursor.

19. The method according to claim 18 wherein the organometallic precursor comprises one of hafnium and aluminium.

20. Apparatus for treating a gas stream, the apparatus comprising:
a gas passage for receiving the gas stream;
a plurality of hollow cathodes located about the gas passage;
means for supplying to the hollow cathodes a gaseous source of reactive species for reacting with a component of the gas stream;
means for applying a potential to the hollow cathodes to form the reactive species from said source; and
a reaction chamber for receiving the gas stream and the reactive species.

21. Apparatus according to claim 20 wherein each hollow cathode comprises a hollow cylindrical tube.

22. Apparatus according to claim 21 wherein the cylindrical tubes are substantially parallel to the gas passage.

23. Apparatus according to claim 21 wherein the cylindrical tubes comprise a plurality of bores formed in an electrically conductive body at least partially housing the gas passage.

24. Apparatus according to claim 23 wherein the supply means comprises a plenum chamber having an inlet for receiving the source of reactive species, and a plurality of outlets from which the source of reactive species is supplied to the hollow cathodes.

25. Apparatus according to claim 20 comprising an anode located downstream from the gas passage and the hollow cathode, the anode having apertures aligned with the gas passage and the hollow cathodes.

26. Apparatus according to claim 25 wherein the anode is located in the reaction chamber.

27. Apparatus according to claim 20 wherein the outlets from the hollow cathodes are substantially co-planar with the outlet from the gas passage.

28. Apparatus according to claim 20 comprising a plurality of said gas passages arranged such that the gas stream passes through the gas passages in parallel, each gas passage being surrounded by a plurality of hollow cathodes.

29. Apparatus according to claim 20 comprising a heater for heating the reaction chamber to promote reaction between the reactive species and the component of the gas stream.

30. Apparatus according to claim 20 wherein the reactor chamber is thermally insulated to promote reaction between the reactive species and the component of the gas stream.

31. Apparatus according to claim 20 comprising a separator for receiving a gas stream exhausted from the reaction chamber and separating solid material from that gas stream.

32. Apparatus according to claim 31 wherein the separator is a cyclone separator.

33. Apparatus for treating a gas stream exhausted from a process chamber to which a first gaseous precursor and a second gaseous precursor are alternately supplied, the apparatus comprising a gas passage for receiving the gas stream, a plurality of hollow cathodes located about the gas passage, means for supplying to the hollow cathodes a gaseous source of reactive species for reacting with one of the first and second gaseous precursors, means for applying a potential to the hollow cathodes to form the reactive species from said source, and a reaction chamber for receiving the gas stream and the reactive species.

34. Apparatus according to claim 33 wherein said one of the first and second gaseous precursors is the first gaseous precursor, and the source of reactive species is the second gaseous precursor.

35. An atomic layer deposition apparatus comprising a process chamber, a first gaseous precursor supply for supplying a first gaseous precursor to the chamber, a second gaseous precursor supply for supplying a second gaseous precursor to the chamber, a vacuum pump for drawing a gas stream from the process chamber, and, between the process chamber and the vacuum pump, a plurality of gas passages for receiving the gas stream from the process chamber, and a plurality of hollow cathodes located about the gas passages for receiving second gaseous precursor from the second precursor gas supply, the apparatus comprising means for applying a potential to the hollow cathodes to form from the second gaseous precursor reactive species for reacting with first gaseous precursor within the gas stream to form solid material, a reaction chamber for receiving the gas stream and the reactive species, and a separator for receiving a gas stream exhausted from the reaction chamber and separating solid material from that gas stream.

36. Apparatus according to claim 33 wherein the first gaseous precursor is an organometallic precursor.

37. Apparatus according to claim 36 wherein the organometallic precursor comprises one of hafnium and aluminium.

38. Apparatus according to claim 33 wherein the second gaseous precursor is an oxidant.

39. Apparatus according to claim 38 wherein the second gaseous precursor is ozone.
